(19) United States
(12) Patent Application Publication
(10) Pub. No.: US 2022/0247383 A1
(43) Pub. Date: Aug. 4, 2022

(54) WIDEBAND FILTER USING TRANSVERSELY-EXCITED FILM BULK ACOUSTIC RESONATORS AND INDUCTIVE CANCELLATION

(71) Applicant: Resonant Inc., Austin, TX (US)

(72) Inventor: Andrew Guyette, San Mateo, CA (US)

(21) Appl. No.: 17/591,682

(22) Filed: Feb. 3, 2022

Related U.S. Application Data
(60) Provisional application No. 63/144,980, filed on Feb. 3, 2021.

(51) Int. Cl. H03H 9/54; H03H 9/56; H03H 9/205

(52) U.S. Cl. CPC H03H 9/542; H03H 9/205; H03H 9/568

(57) ABSTRACT

There are disclosed acoustic filter circuits. A filter circuit includes a first capacitor connected between an input and a first node, a first inductor coupled between the first node and ground, a series resonant circuit comprising a first acoustic resonator and a second inductor connected between the first node and a second node, and a shunt resonant circuit comprising a second acoustic resonator and a third inductor connected between the second node and ground. The first inductor and the third inductor are inductively coupled with a negative mutual inductance.

### RELATED APPLICATION INFORMATION

This patent claims priority from provisional patent application 63/144,980, filed Feb. 3, 2021, entitled WIDEBAND XBAR FILTER USING INDUCTIVE CANCELLATION.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to radio frequency filters using acoustic wave resonators, and specifically to filters for use in communications equipment.

### Description of the Related Art

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a passband or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5^{th} generation mobile networks is defined in the 5G NR (new radio) standard. The 5G NR standard defines several new communications bands. Two of these new communications bands are n77, which uses the frequency range from 3300 MHz to 4200 MHz, and n79, which uses the frequency range from 4400 MHz to 5000 MHz. Both band n77 and band n79 use time-division duplexing (TDD), such that a communications device operating in band n77 and/or band n79 use the same frequencies for both uplink and downlink transmissions. Bandpass filters for bands n77 and n79 must be capable of handling the transmit power of the communications device. The 5G NR standard also defines millimeter wave communication bands with frequencies between 24.25 GHz and 40 GHz.

The Unlicensed National Information Infrastructure (U-NII) band, as defined by the United States Federal Communications Commission, is the portion of the radio frequency spectrum from 5.15 GHz to 7.125 GHz. The U-NII band is used by wireless local area networks (WLANs) and by many wireless Internet service providers. U-NII consists of eight ranges. Portions of U-NII-1 through U-NII-4 are used for 5 GHz WLANs based on the Institute of Electrical and Electronic Engineers (IEEE) Standard 802.11a and newer standards (commonly referred to as 5 GHz Wi-Fi®). U-NII-5 though U-NII-8 are allocated for 6 GHz WLANs based on the Institute of Electrical and Electronic Engineers (IEEE) Standard 802.11ax (commonly referred to as Wi-Fi 6E). The U-NII frequency ranges also require high frequency and wide bandwidth bandpass filters.

The Transversely-Excited Film Bulk Acoustic Resonator (XBAR) is an acoustic resonator structure for use in microwave filters. The XBAR is described in U.S. Pat. No. 10,491,291, titled TRANSVERSELY EXCITED FILM BULK ACOUSTIC RESONATOR. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz. Matrix XBAR filters are also suited for frequencies between 1 GHz and 3 GHz.

### DESCRIPTION OF THE DRAWINGS

FIG. 1 includes a schematic plan view, two schematic cross-sectional views, and a detailed cross-sectional view of a transversely-excited film bulk acoustic resonator (XBAR).

FIG. 2A is an equivalent circuit model of an acoustic resonator.

FIG. 2B is a graph of the admittance of an ideal acoustic resonator.

FIG. 2C is a circuit symbol for an acoustic resonator.

FIG. 3 is a schematic diagram of a bandpass filter using acoustic resonators.

FIG. 4A is a schematic diagram of a two-port network including an acoustic resonator.

FIG. 4B is a graph of the magnitude of the input-output transfer function of an example of the two-port network of FIG. 4A.

FIG. 5 is a schematic diagram of a two-port network including two acoustic resonators and including inductive cancellation.

FIG. 6 is a graph of the magnitude of the input-output transfer function of an example of the two-port network of FIG. 5.

FIG. 7 is a block diagram of a bandpass filter using inductive cancellation.

FIG. 8 is a schematic diagram of a bandpass filter using inductive cancellation.

FIG. 9 is a graph of the magnitude of the input-output transfer function of an example of the filter of FIG. 8.

FIG. 10 is an expanded portion of the graph of FIG. 9.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

Description of Apparatus

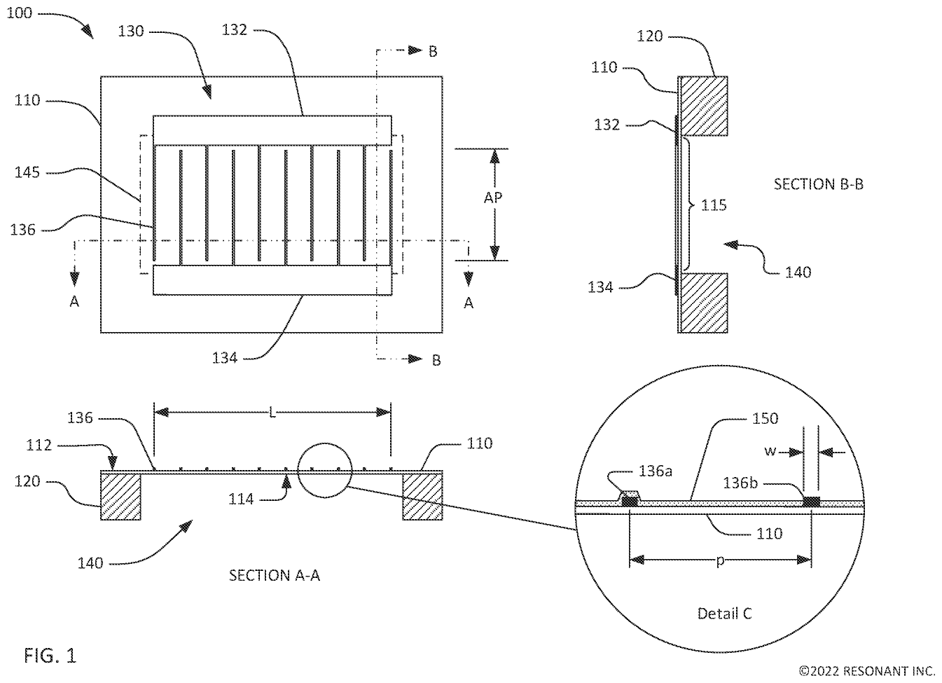

FIG. 1 shows a simplified schematic top view, orthogonal cross-sectional views, and a detailed cross-sectional view of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz. The matrix XBAR filters described in this patent are also suited for frequencies above 1 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. The piezoelectric plate may be Z-cut (which is to say the Z axis is normal to the front and back surfaces 112, 114), rotated Z-cut, or rotated YX cut. XBARs may be fabricated on piezoelectric plates with other crystallographic orientations.

The back surface 114 of the piezoelectric plate 110 is attached to a surface of the substrate 120 except for a portion of the piezoelectric plate 110 that forms a diaphragm 115 spanning a cavity 140 formed in the substrate. The portion of the piezoelectric plate that spans the cavity is referred to herein as the “diaphragm” 115 due to its physical resemblance to the diaphragm of a microphone. As shown in FIG. 1, the diaphragm 115 is contiguous with the rest of the piezoelectric plate 110 around all of a perimeter 145 of the cavity 140. In this context, “contiguous” means “continuously connected without any intervening item”. In other configurations, the diaphragm 115 may be contiguous with the piezoelectric plate around at least 50% of the perimeter 145 of the cavity 140.

The substrate 120 provides mechanical support to the piezoelectric plate 110. The substrate 120 may be, for example, silicon, sapphire, quartz, or some other material or combination of materials. The back surface 114 of the piezoelectric plate 110 may be bonded to the substrate 120 using a wafer bonding process. Alternatively, the piezoelectric plate 110 may be grown on the substrate 120 or attached to the substrate in some other manner. The piezoelectric plate 110 may be attached directly to the substrate or may be attached to the substrate 120 via one or more intermediate material layers (not shown in FIG. 1).

“Cavity” has its conventional meaning of “an empty space within a solid body.” The cavity 140 may be a hole completely through the substrate 120 (as shown in Section A-A and Section B-B) or a recess in the substrate 120 under the diaphragm 115. The cavity 140 may be formed, for example, by selective etching of the substrate 120 before or after the piezoelectric plate 110 and the substrate 120 are attached.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The term “busbar” is conventionally used to denote a conductor that provides power to or interconnects other elements. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. The primary acoustic mode of an XBAR is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

The IDT 130 is positioned on the piezoelectric plate 110 such that at least the fingers of the IDT 130 are disposed on the diaphragm 115 of the piezoelectric plate which spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may have more or fewer than four sides, which may be straight or curved.

The detailed cross-section view (Detail C) shows two IDT fingers 136a, 136b on the surface of the piezoelectric plate 110. The dimension p is the “pitch” of the IDT and the dimension w is the width or “mark” of the IDT fingers. A dielectric layer 150 may be formed between and optionally over (see IDT finger 136a) the IDT fingers. The dielectric layer 150 may be a non-piezoelectric dielectric material, such as silicon dioxide or silicon nitride. The dielectric layer 150 may be formed of multiple layers of two or more materials. The IDT fingers 136a and 136b may be aluminum, copper, beryllium, gold, tungsten, molybdenum, alloys and combinations thereof, or some other conductive material. Thin (relative to the total thickness of the conductors) layers of other metals, such as chromium or titanium, may be formed under and/or over and/or as layers within the fingers to improve adhesion between the fingers and the piezoelectric plate 110 and/or to passivate or encapsulate the fingers and/or to improve power handling. The busbars of the IDT 130 may be made of the same or different materials as the fingers.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds of parallel fingers in the IDT 110. Similarly, the thickness of the fingers in the cross-sectional views is greatly exaggerated.

An XBAR based on shear acoustic wave resonances can achieve better performance than current state-of-the art surface acoustic wave (SAW), film-bulk-acoustic-resonators (FBAR), and solidly-mounted-resonator bulk-acoustic-wave (SMR BAW) devices. In particular, the piezoelectric coupling for shear wave XBAR resonances can be high (>20%) compared to other acoustic resonators. High piezoelectric coupling enables the design and implementation of microwave and millimeter-wave filters of various types with appreciable bandwidth.

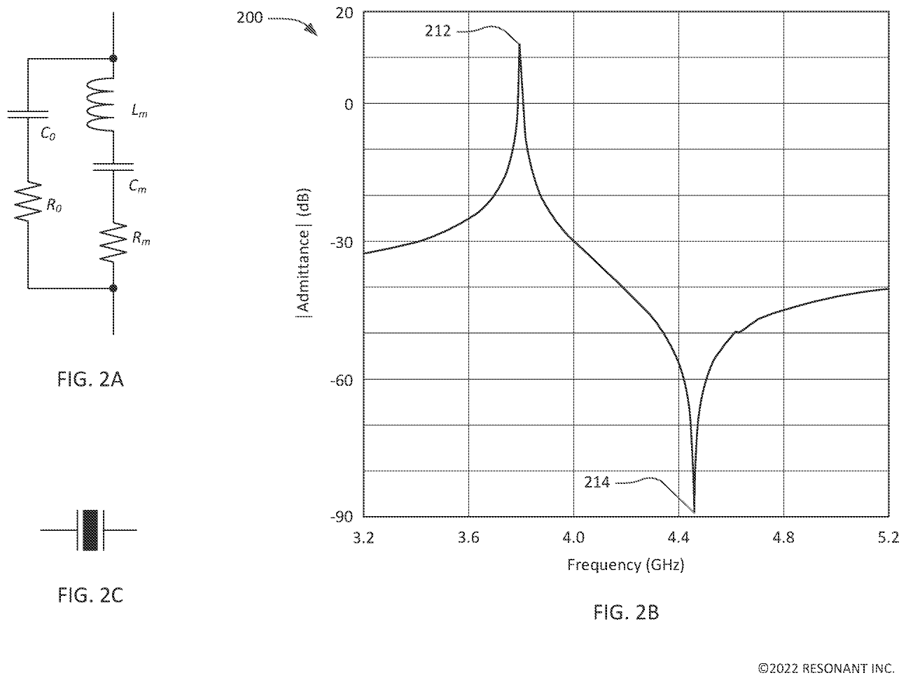

The basic behavior of acoustic resonators, including XBARs, is commonly described using the Butterworth Van Dyke (BVD) circuit model as shown in FIG. 2A. The BVD circuit model consists of a motional arm and a static arm. The motional arm includes a motional inductance Lₘ, a motional capacitance Cₘ, and a resistance Rₘ. The static arm includes a static capacitance C₀ and a resistance R₀. While the BVD model does not fully describe the behavior of an acoustic resonator, it does a good job of modeling the two primary resonances that are used to design band-pass filters, duplexers, and multiplexers (multiplexers are filters with more than 2 input or output ports with multiple passbands).

The first primary resonance of the BVD model is the motional resonance caused by the series combination of the motional inductance Lₘ and the motional capacitance Cₘ. The second primary resonance of the BVD model is the anti-resonance caused by the combination of the motional inductance Lₘ, the motional capacitance Cₘ, and the static capacitance C₀. In a lossless resonator (Rₘ=R₀=0), the frequency Fᵣ of the motional resonance (e.g., the “resonance frequency”) is given by

$${F}_{r} = \frac{1}{2 π \sqrt{{L}_{m} {C}_{m}}} \qquad ( 1 )$$

The frequency Fₐ of the anti-resonance (e.g., the “anti-resonance frequency”) is given by

$${F}_{a} = {F}_{r} \sqrt{1 + \frac{1}{γ}} \qquad ( 2 )$$

where γ=C₀/Cₘ is dependent on the resonator structure and the type and the orientation of the crystalline axes of the piezoelectric material.

FIG. 2B is a graph 200 of the magnitude of admittance of a theoretical lossless acoustic resonator. The data in FIG. 2B and subsequent figures was derived by simulation using a finite element method. The acoustic resonator has a resonance 212 at a resonance frequency where the admittance of the resonator approaches infinity. The resonance is due to the series combination of the motional inductance Lₘ and the motional capacitance Cₘ in the BVD model of FIG. 2A. The acoustic resonator also exhibits an anti-resonance 214 where the admittance of the resonator approaches zero. The anti-resonance is caused by the combination of the motional inductance Lₘ, the motional capacitance Cₘ, and the static capacitance C₀. In a lossless resonator (Rₘ=R₀=0), the frequency Fᵣ of the resonance is given by

$${F}_{r} = \frac{1}{2 π \sqrt{{L}_{m} {C}_{m}}} \qquad ( 1 )$$

The frequency Fₐ of the anti-resonance is given by

$${F}_{a} = {F}_{r} \sqrt{1 + \frac{1}{γ}} \qquad ( 2 )$$

In over-simplified terms, the lossless acoustic resonator can be considered a short circuit at the resonance frequency 212 and an open circuit at the anti-resonance frequency 214. The resonance and anti-resonance frequencies in FIG. 2B are representative, and an acoustic resonator may be designed for other frequencies.

FIG. 2C shows the circuit symbol for an acoustic resonator such as an XBAR. This symbol will be used to designate each acoustic resonator in schematic diagrams of filters in subsequent figures.

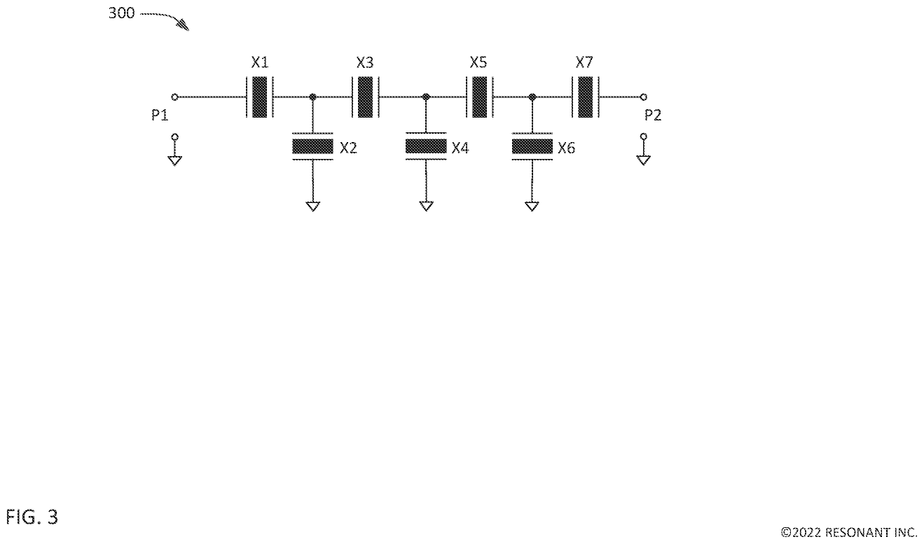

FIG. 3 is a simplified schematic circuit diagram of an exemplary RF filter circuit 300 incorporating seven acoustic wave resonators, labeled X1 through X7, arranged in what is commonly called a “ladder” circuit configuration, or a “half ladder” circuit configuration. A filter of this configuration is commonly used for band-pass filters in communications devices. The filter circuit 300 may be, for example, a transmit filter or a receive filter for incorporation into a communications device. The filter circuit 300 is a two-port network where one terminal of each port is typically connected to a signal ground. The filter circuit 300 includes four series resonators (X1, X3, X5, and X7) connected in series between a first port (P1) and second port (P2). In this patent, the term “series” used as an adjective (e.g. series resonator, series inductor, series capacitor, series resonant circuit) means a component connected in series with other component along signal path extending from the input to the output of a network. Either port may be the input to the filter, with the other port being the output. The filter circuit 300 includes three shunt resonators (X2, X4, and X6). Each shunt resonator is connected between ground and a junction of adjacent series resonators. Other filters may include shunt resonators connected from the input and/or output port and ground. In this patent, the term “shunt” used as an adjective (e.g. shunt resonator, shunt inductor, shunt resonant circuit) means a component connected from a node along the series signal path to ground. The schematic diagram of FIG. 3 is simplified in that passive components, such as the inductances inherent in the conductors interconnecting the resonators, are not shown. The use of seven acoustic wave resonators, four series resonators, and three shunt resonators is exemplary. A band-pass filter circuit may include more than, or fewer than, seven resonators and more than, or fewer than, four series resonators and three shunt resonators. For example, there may be three series resonators and two shunt resonators.

Each acoustic wave resonator X1 to X7 may be a transversely-excited film bulk acoustic resonator (XBAR) as shown in FIG. 1 and/or as described in application Ser. No. 16/230,443.

As shown in FIG. 2B, each acoustic resonator exhibits very high admittance at a resonance frequency 212 and very low admittance at an anti-resonance frequency 214 higher than the resonance frequency. In simplified terms, each resonator is approximately a short circuit at its resonance frequency and an open circuit at its anti-resonance frequency. Thus, the transmission between Port 1 and Port 2 of the band-pass filter circuits 300 is very low at the resonance frequencies of the shunt resonators since they nearly short circuit the transmission to ground, and the anti-resonance frequencies of the series resonators since they nearly open circuit the transmission from reaching between the ports. The frequencies where the filter transmission is very low are commonly referred to as “transmission zeros” although the transmission through the filter will not be exactly zero. In a typical ladder or half ladder band-pass filter, the resonance frequencies of shunt resonators are less than a lower edge of the filter passband (e.g., passband frequencies) to create transmission zeros at frequencies below the passband. The anti-resonance frequencies of shut resonators typically fall within the passband of the filter to create almost no effect at frequencies in the passband. Conversely, the anti-resonance frequencies of series resonators are greater than an upper edge of the passband to create transmission zeros at frequencies above the passband. The resonance frequencies of series resonators typically fall within the passband of the filter. In some designs, one or more shunt resonators may have resonance frequencies higher than the upper edge of the passband frequencies to ensure transmission zeros at frequencies above the passband. To ensure that the anti-resonance frequencies of shunt resonators and the resonance frequencies of series resonator are within the passband, the differences between the resonance and anti-resonance frequencies of each of the filter resonators are typically smaller than the bandwidth of the filter. In some cases, the differences between the resonance and anti-resonance frequencies of all resonators are typically smaller than the bandwidth of the filter.

To provide a filter with uniform transmission in the passband and adequate stopbands above and below the passband, it is generally necessary for (1) the resonators to be free of significant spurious modes at frequencies within the passband, (2) the transmission zeros be distributed at multiple frequencies above and below the passband, and (3) the antiresonance frequencies of shunt resonators and the resonance frequencies of series resonators be distributed at multiple frequencies within the passband. These requirements limit the bandwidth of a filter to a maximum of about 1.6 times the differences between the resonance and anti-resonance frequencies of the resonators.

For example, the admittance characteristic graphed in FIG. 2B is representative of an XBAR using a rotated Y-cut lithium niobate piezoelectric plate as described in U.S. Pat. No. 10,790,802. Rotated Y-cut XBARs have the highest electromechanical coupling and thus the widest separation between their resonance and anti-resonance frequencies. The difference between the anti-resonance and resonance frequencies of the example resonator is about 650 MHz. Rotated Y-cut XBAR resonators are suitable to implement filters for 5G NR Band n77, which has a bandwidth of 900 MHz. The example resonator may be suitable for use as a series resonator in a Band n77 filter.

The resonance frequency of an XBAR is primarily determined by the thickness of the diaphragm including the piezoelectric plate and dielectric layers if present. The difference between the anti-resonance and resonance frequencies of an XBAR scales with the resonance frequency. XBARs may be used in filters for various frequency bands if the required relative bandwidth if the filter (i.e. the bandwidth divided by the center frequency) is not greater than about 0.24. XBARs cannot be used to implement a filter for the entire U-NII band, which has a relative bandwidth greater than 0.32, without additional reactive components.

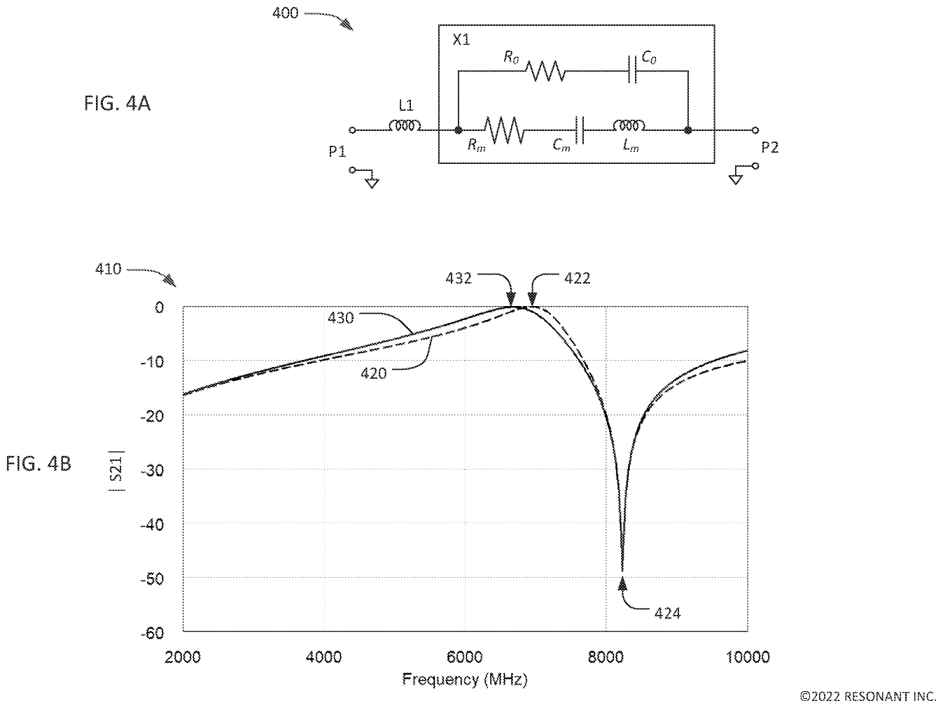

Reactive components, such as inductors and/or capacitors, may be incorporated in filters to provide filter bandwidth that cannot be achieved using only XBARs. FIG. 4A is a schematic diagram of a two-port resonant circuit 400 that combines an acoustic resonator X1 and an inductor L1 in series. The acoustic resonator X1 is represented by the BVD equivalent circuit model. The inductor L1 is additive with the motional inductance Lₘ of X1. This lowers the resonance frequency of the resonance circuit 400 compared to the resonance frequency of the resonator X1 in isolation.

FIG. 4B is a graph 410 of the input-output transfer function S21 of an exemplary resonant circuit as shown in FIG. 2A. The dashed curve 420 is a plot of the magnitude of the admittance of the input-output transfer function when the inductance value of L1 is zero, which is the input-output transfer function of the resonator X1 alone. The dashed curve 420 has a maximum 422 at the resonance frequency of X1 and a minimum 424 at the anti-resonance frequency of X1. The solid curve 430 is a plot of the magnitude of the admittance of the input-output transfer function when the inductance value of L1 is finite. The solid curve 430 has a maximum 432 at a frequency lower than the resonance frequency of X1. The difference between the frequencies of the maximum 422 and the maximum 432 is determined by the inductance value of L1. The solid curve 430 has a minimum at the anti-resonance frequency of X1.

The inductor L1 may be implemented, for example, by a conductor (e.g., forming an inductor) on the chip containing the XBAR X1, by a conductor on a printed wiring board coupled to the XBAR chip, or as a discrete chip inductor. In all cases, the Q-factor of the inductor is typically significantly less than the Q-factor of the XBAR. To avoid excessive loss in the inductor, the inductance value of L1 may be limited to a small fraction of the motion inductance Lₘ of the XBAR.

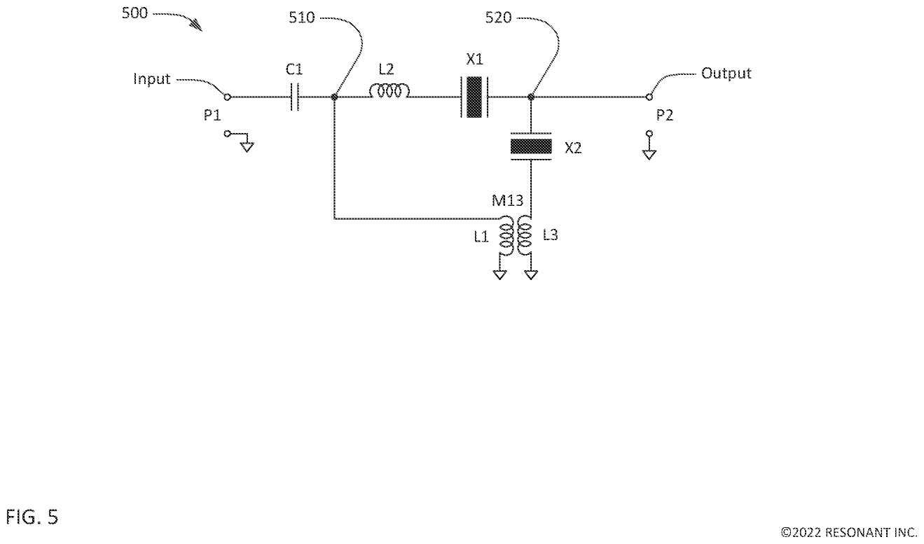

FIG. 5 is a schematic diagram of a two-port network 500 including two XBARs X1, X2. The network 500 is a filter circuit of sorts but is more useful as a building block in more complex filter circuits. The network 500 has a first port P1 and a second port P2. The ungrounded terminal of the first port will be considered the input to the filter circuit. The ungrounded terminal of the second port will be considered the output of the filter circuit. The filter circuit is bidirectional and either ungrounded terminal could be the input or output.

A series capacitor C1 is connected from the input to a first node 510. A shunt inductor L1 is connected from the first node 510 to ground. The series capacitor C1 and shunt inductor L1 form an impedance matching network to match, or approximately equal, the impedance at the input port to a target impedance value. The impedance value is typically, but not necessarily, 50 ohms. A tolerance on impedance at the input port may be specified, for example, by a maximum return loss or a voltage standing wave ratio (VSWR) at the input port. The series capacitor C1 raises the impedance of the filter circuit and decreases the required static capacitance (C₀ in FIG. 2A), and thus the physical size, of the XBARs.

XBAR X1 and inductor L2 form a first resonant circuit, as previously shown in FIG. 4A, connected between the first node 510 and a second node 520, which is also connected to the output. The first resonant circuit X1/L2 (e.g., X1 and L2) can be described as a “series” resonant circuit (e.g., functioning like a series resonator of a bandpass filter) since it lies along a direct path, comprising multiple components (including capacitor C1) in series, from the input to the output of the filter circuit. XBAR X2 and inductor L3 form a second resonant circuit X2/L3 connected from the second node 520 to ground. The second resonant circuit X2/L3 may be described as a “shunt” resonant circuit (e.g., functioning like a shunt resonator of a bandpass filter) since one side of the resonant circuit is grounded.

Shunt inductor L1 is coupled to inductor L3 with a mutual inductance M13. The coupling between L1 and L3 provides a signal path from the input to the output that bypasses the series resonant circuit X1/L2. When the mutual inductance M13 is negative, the signal path through the coupled inductors is phase-reversed with respect to the signal path through the series resonant circuit X1/L2. The phase-reversed signal path has the effect of canceling a portion of the static capacitance C₀ of X1, which increases the anti-resonance frequency of the series resonant circuit X1/L2. The technique of using negative inductive coupling to cancel the static capacitance of an acoustic resonator will be subsequently referred to as “inductive cancellation”.

The inductors L1, L2, and L3 may be implemented, for example, by conductors (e.g., forming inductors) on the chip containing the XBARs X1 and X2, or by conductors on a printed wiring board coupled to the XBAR chip. The capacitor C1 may be a MIM (metal-insulator-metal) capacitor on the chip containing the XBARs X1 and X2, or a multilayer capacitor on a printed wiring board coupled to the XBAR chip. Alternatively, the capacitor C1 may be formed by interdigitated fingers on the chip containing the XBARs.

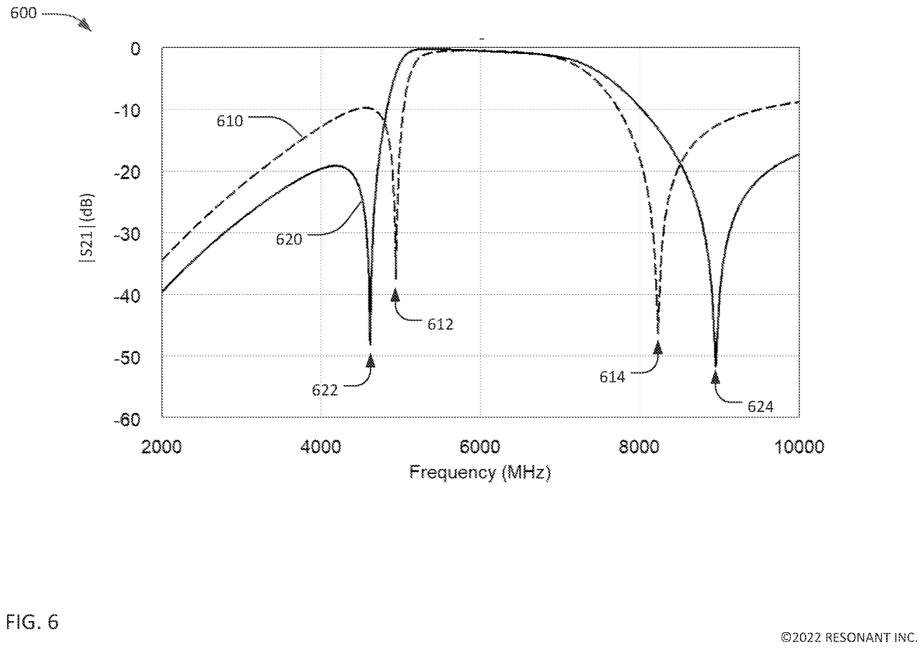

FIG. 6 is a graph of the input/output transfer function S21 of an embodiment of the two-port network 500 of FIG. 5. The dashed curve 610 is a plot of the magnitude of S21 for an embodiment where the mutual inductance M13 is zero, which is to say an embodiment without inductive cancellation. The input/output transfer function has a first transmission zero 612 at the resonance frequency of the shunt resonant circuit X2/L3. The input/output transfer function has a second transmission zero 614 at the anti-resonance frequency of the series resonant circuit X1/L2.

The solid curve 620 is a plot of the magnitude of S21 for an embodiment where the mutual inductance M13 is finite and negative, which is to say an embodiment using inductive cancellation. The input/output transfer function has a first transmission zero 622 at frequency lower than the frequency of the first transmission zero 612 with M13=0. The input/output transfer function has a second transmission zero 624 at a frequency above the frequency of the second transmission zero 614 with M13=0. The increase in the frequency of the second transmission zero is due to inductive cancellation by mutual inductance M13 of a portion of the static capacitance C₀ of X1.

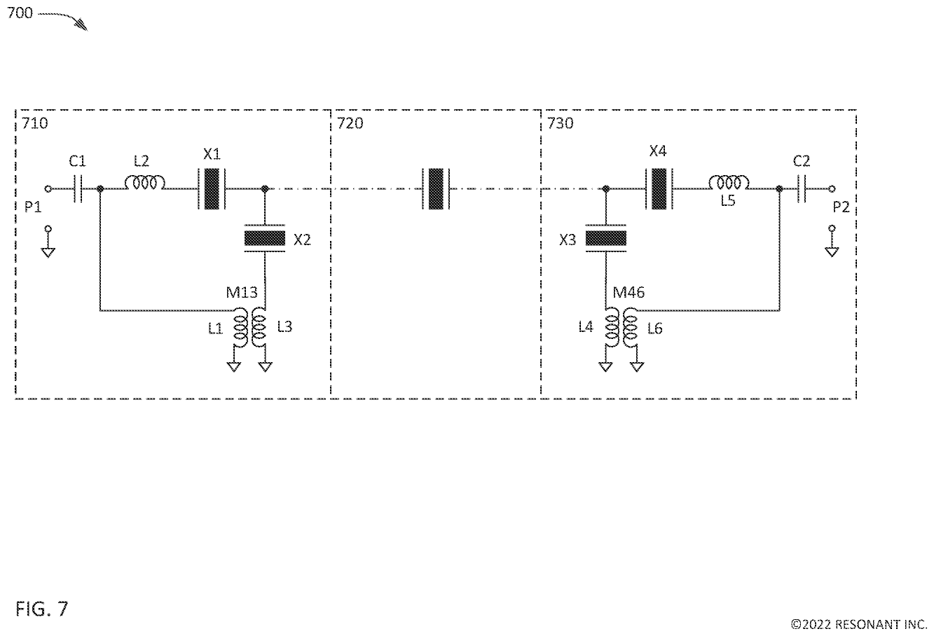

FIG. 7 is a block diagram of a bandpass filter 700 using inductive cancellation. The filter 700 is bi-directional and either port 1 or port 2 could serve as the input to or output from the filter. For ease of explanation, it is assumed the signal flow is from left to right such that Port 1 is the input port and Port 2 is the output port.

The filter 700 includes an input section 710, an intermediate section 720, and an output section 730. The input section 710 is an embodiment of the circuit previously shown in FIG. 5. The capacitor C1 and inductor L1 match the input impedance at port 1 to a desired impedance value, which is typically, but not necessarily, 50 ohms. XBAR X1 and inductor L2 form a series resonant circuit. XBAR X2 and inductor L3 form a shunt resonant circuit. Shunt inductor L1 is coupled to inductor L3 with a negative mutual inductance M13, which cancels a portion of the static capacitance C₀ of X1 and increases the anti-resonance frequency of the series resonant circuit X1 and L2. Negative mutual inductance M13 provides inductive cancellation as noted for FIG. 5 between an input at port P1 and an output of section 710 at that section's connection with section 720 (e.g., at a node at the connection).

The output section 720 is another embodiment of the circuit previously shown in FIG. 5. The series capacitor C2 and shunt inductor L6 match the output impedance at port 2 to a desired impedance value, which is typically, but not necessarily, 50 ohms. The input impedance at port 1 and the output impedance at port 2 need not be the same. XBAR X4 and inductor L5 form a series resonant circuit. XBAR X3 and inductor L4 form a shunt resonant circuit. Shunt inductor L6 is coupled to inductor L4 with a negative mutual inductance M46, which cancels a portion of the static capacitance C₀ of X4 and increases the anti-resonance frequency of the series resonant circuit X4 and L5. Negative mutual inductance M46 provides inductive cancellation as noted for FIG. 5 between an input at section 730's connection with section 720 (e.g., at a node at the connection) and an output at port P2. The increase in the frequency of a transmission zero of section 730 may be due to inductive cancellation by mutual inductance M46 of a portion of the static capacitance C₀ of X4. The reduction is the frequency of a transmission zero section 730 may be due to an effective increase in the inductance by mutual inductance M46 in the first shunt resonant circuit (i.e. the effective inductance in series with X3).

The intermediate section 720 couples the input section 710 to the output section 730. The intermediate section 720 will include at least one series resonator between the input section 710 to the output section 730 and may contain additional resonators and/or reactive components.

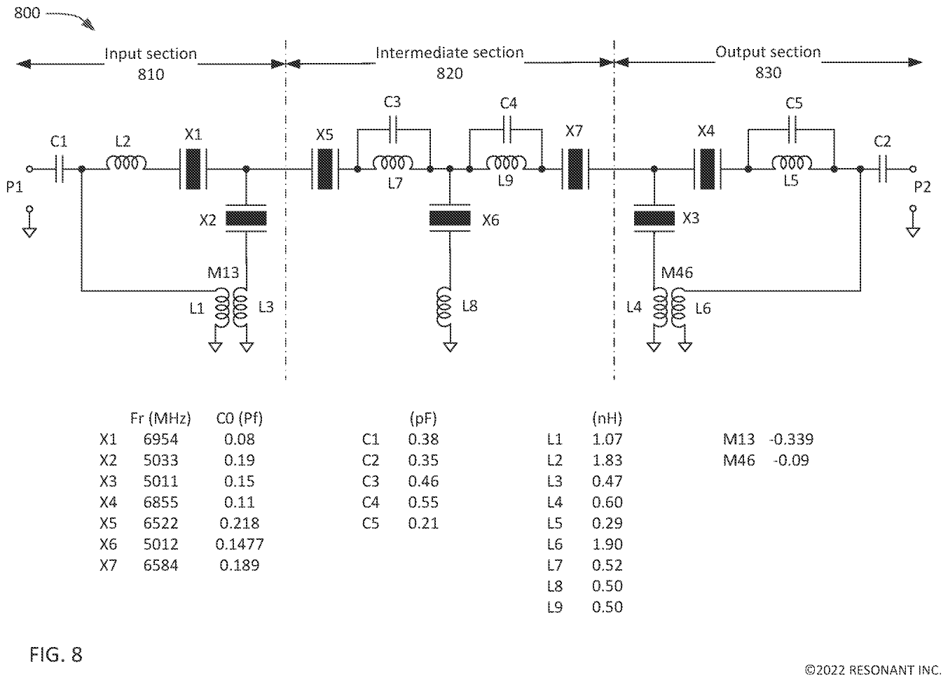

FIG. 8 is a schematic diagram of a U-NII bandpass filter 800 implemented with XBAR resonators and inductive cancellation. The filter 800 is bi-directional and either port P1 or port P2 could serve as the input to or output from the filter. For ease of explanation, it is assumed the signal flow is from left to right such that Port 1 is the input port and Port 2 is the output port.

The filter 800 includes an input section 810, an intermediate section 820, and an output section 830. The input section 810 and the output section 830 are the same as the input and output sections 710 and 730 of filter 700 of FIG. 7, except for the addition of capacitor C5 in parallel with inductor L5. The intermediate section 820 includes series resonant circuit X5/L7 and X7/L9 connected between the input section 810 and the output section 830 and shunt resonant circuit X6/L8.

Capacitor C3 and inductor L7 form a parallel LC resonant circuit that creates an additional transmission zero at a frequency above the upper edge of the filter passband. Similarly, capacitor C4 in parallel with inductor L9 and capacitor C5 in parallel with inductor L5 provide two additional transmission zeros at frequencies above the upper edge of the filter passband. Negative mutual inductances M13 and M46 of FIG. 8 provide inductive cancellation as noted for FIG. 7.

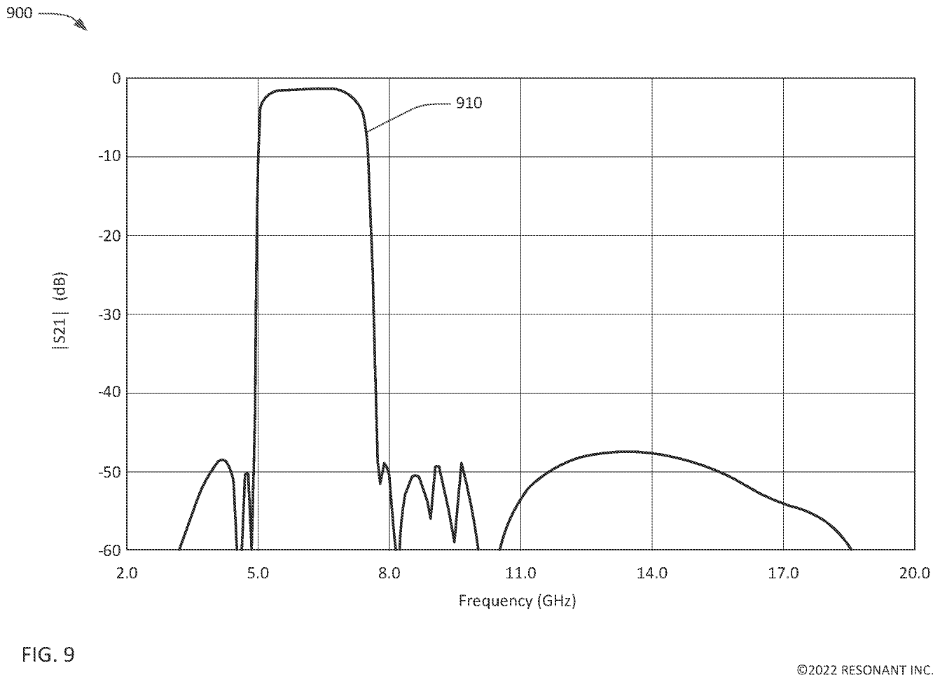

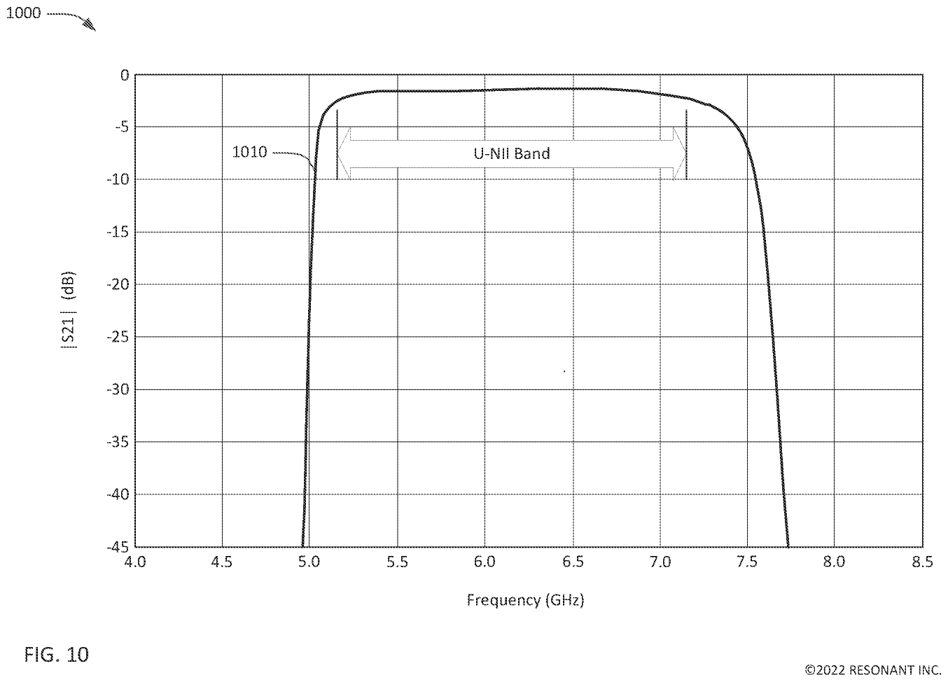

FIG. 9 and FIG. 10 are graphs 900 and 1000 of the performance of an embodiment of the filter 800 of FIG. 8. Specifically, the solid curve 910 in FIG. 9 is a plot of the magnitude of the input/output transfer function of the filter as a function of frequency. The solid curve 1010 in FIG. 10 is an expanded portion of the curve 910. The passband of the filter 800 spans the U-NII frequency range from 5.15 to 7.125 GHz. The transmission zeros at frequencies below the passband are created by the shunt resonant circuits X2/L3, X6/L8, and X3/L4. The transmission zeros at frequencies just above the passband are created by series resonant circuits X1/L2, X5/L7, X7/L9, and X4/L5. Transmission zeros at 9.5 GHz, 10.2 GHz, and 19 GHz are created by the LC resonant circuits C3/L7, C4/L9, and C5/L5. Negative mutual inductances M13 and M46 of FIG. 8 provide inductive cancellation as noted for FIG. 7, which are included in graphs 900 and 1000

Specific component values are provided in FIG. 8. These component values are exemplary. Similar filter performance may be obtained with innumerable sets of different component values for the same schematic diagram. The similar performances may have a different bandpass and/or different transmission zeros.

Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. A filter circuit, comprising:
a first capacitor connected between an input and a first node;
a first inductor coupled between the first node and ground;
a series resonant circuit comprising a first acoustic resonator and a second inductor connected between the first node and a second node; and
a shunt resonant circuit comprising a second acoustic resonator and a third inductor connected between the second node and ground, wherein
the first inductor and the third inductor are inductively coupled with a negative mutual inductance.

2. The filter circuit of claim 1, wherein the first and second acoustic resonators are transversely-excited film bulk acoustic resonators (XBARs).

3. The filter circuit of claim 2, wherein the first and second acoustic resonators each comprise a rotated Y-cut lithium niobate piezoelectric plate.

4. The filter circuit of claim 1, wherein the first capacitor and the first inductor are configured to match an impedance at the input to a target impedance value.

5. The filter circuit of claim 1, wherein the negative mutual inductance cancels a portion of the static capacitance C₀ of the first acoustic resonator.

6. The filter circuit of claim 1, wherein the negative mutual inductance reduces a first frequency of a transmission zero of the filter circuit.

7. The filter circuit of claim 1, wherein the series resonator is a first series resonator, the shunt resonator is a first shunt resonator, and the negative mutual inductance is a first negative mutual inductance; and further comprising:
a second capacitor connected between an output and a fourth node;
a sixth inductor coupled between the fourth node and ground;
a second series resonant circuit comprising a fourth acoustic resonator and a fifth inductor connected between the fourth node and a third node;
a second shunt resonant circuit comprising a third acoustic resonator and a fourth inductor connected between the third node and ground, wherein
the fifth inductor and the fourth inductor are inductively coupled with a second negative mutual inductance; and
an intermediate section including a third series resonant circuit connected between the second node and the third node.

8. The filter circuit of claim 7, wherein the third and fourth acoustic resonators are transversely-excited film bulk acoustic resonators (XBARs).

9. The filter circuit of claim 8, wherein the third and fourth acoustic resonators each comprise a rotated Y-cut lithium niobate piezoelectric plate.

10. The filter circuit of claim 7, wherein the second capacitor and the sixth inductor are configured to match an impedance at the output to a target impedance value.

11. The filter circuit of claim 7, wherein the second negative mutual inductance cancels a portion of the static capacitance C₀ of the second acoustic resonator.

12. The filter circuit of claim 7, wherein the second negative mutual inductance reduces a second frequency of a transmission zero of the filter circuit.

13. The filter circuit of claim 7, wherein the third series resonant circuit includes:
a fifth and a seventh acoustic resonator coupled in series between the second node and the third node; and
a sixth acoustic resonator coupled to ground from between the fifth and a seventh acoustic resonators.

14. A filter circuit, comprising:
a first inductor coupled between a first node and ground;
a first series resonant circuit comprising a first acoustic resonator and a second inductor connected between the first node and a second node; and
a first shunt resonant circuit comprising a second acoustic resonator and a third inductor connected between the second node and ground, wherein
the first inductor and the third inductor are inductively coupled with a first negative mutual inductance;
a sixth inductor coupled between a fourth node and ground;
a second series resonant circuit comprising a fourth acoustic resonator and a fifth inductor connected between the fourth node and a third node;
a second shunt resonant circuit comprising a third acoustic resonator and a fourth inductor connected between the third node and ground, wherein
the fifth inductor and the fourth inductor are inductively coupled with a second negative mutual inductance; and
an intermediate section including a third series resonant circuit connected between the second node and the third node.

15. The filter circuit of claim 14, wherein the first, second, third and fourth acoustic resonators are transversely-excited film bulk acoustic resonators (XBARs).

16. The filter circuit of claim 15, wherein the first, second, third and fourth acoustic resonators each comprise a rotated Y-cut lithium niobate piezoelectric plate.

17. The filter circuit of claim 14, wherein the first and second negative mutual inductances cancel a portion of the static capacitance C₀ of the first and second acoustic resonators.

18. The filter circuit of claim 14, wherein the first and second negative mutual inductances reduce a first and second frequency of a transmission zero of the filter circuit.
